(19) United States
(12) Patent Application Publication
(10) Pub. No.: US 2022/0100319 A1
(43) Pub. Date: Mar. 31, 2022

(54) TOUCH CONTROL SUBSTRATE AND MANUFACTURING METHOD THEREOF, DISPLAY SUBSTRATE AND MANUFACTURING METHOD THEREOF, DISPLAY DEVICE AND MANUFACTURING METHOD THEREOF

(71) Applicants: Chengdu BOE Optoelectronics Technology Co., Ltd., Chengdu, Sichuan (CN); BOE TECHNOLOGY GROUP CO., LTD., Beijing (CN)

(72) Inventors: Mingqiang WANG, Beijing (CN); Yufeng CHEN, Beijing (CN); Zhi YANG, Beijing (CN); Xin BI, Beijing (CN); Bin ZHANG, Beijing (CN)

(21) Appl. No.: 17/427,243

(22) PCT Filed: Jan. 22, 2021
(86) PCT No.: PCT/CN2021/073256

§ 371 Date: Jul. 30, 2021

(30) Foreign Application Priority Data
Jan. 22, 2020 (CN) 202010075521.9

(51) Int. Cl. G06F 3/044; G06F 3/041; H01L 27/32

(52) U.S. Cl. CPC G06F 3/0446; G06F 3/04164; G06F 2203/04103; G06F 2203/04102; G06F 2203/04111; H01L 27/323

(57) ABSTRACT

Provided are a touch control substrate, a display substrate a display device. The touch control substrate has a touch control area and a bonding area and includes: a base; first signal lines; second signal lines; touch control units in the touch control area, each row of touch control units are coupled to one first signal line, each column of touch control units are coupled to one second signal line, first signal lead-in terminals, coupled to first first fan-out lines in the bonding area, of some first signal lines are on a first side of the touch control area, second signal lead-in terminals, coupled to second first fan-out lines in the boding area, of the remaining first signal lines are on a second side of the touch control area, third signal lead-in terminals of the second signal lines are coupled to second fan-out lines in the bonding area.

### CROSS REFERENCE TO RELATED APPLICATIONS

The present application claims priority from a Chinese patent application No. 202010075521.9, filed on Jan. 22, 2020, the entire contents of which are incorporated herein by reference.

### TECHNICAL FIELD

The present disclosure relates to the field of display technology, in particular, to a touch control substrate, a display substrate and a display device.

### BACKGROUND

In a display device, according to different combination of a touch control substrate and a display substrate, a touch screen generally includes: an out-cell touch screen (in which a touch substrate is attached to a display screen), an on-cell touch screen (in which a touch substrate is formed on a display screen), an in-cell touch screen (in which a touch substrate is formed on a display substrate in a display panel).

### SUMMARY

In a first aspect, an embodiment of the present disclosure provides a touch control substrate having a touch control area and a bonding area, the touch control substrate includes: a base; a plurality of first signal lines and a plurality of second signal lines on the base; a plurality of touch control units arranged in an array on the base and in the touch control area, touch control units in a same row are coupled to a same first signal line and touch control units in a same column are coupled to a same second signal line, each of the plurality of first signal lines and the plurality of second signal lines has a signal lead-in terminal, and first signal lead-in terminals of part of the first signal lines are located on a first side of the touch control area, second signal lead-in terminals of the other part of the first signal lines are located on a second side of the touch control area opposite to the first side, the first signal lead-in terminals of the part of the first signal lines are electrically coupled to corresponding first first fan-out lines, respectively, the second signal lead-in terminals of the other part of the first signal lines are electrically coupled to second first fan-out lines, respectively, and the first first fan-out lines and the second first fan-out lines are located in the bonding area, third signal lead-in terminals of the plurality of second signal lines are electrically coupled to corresponding second fan-out lines, respectively, the second fan-out lines are located in the bonding area, and the bonding area is located at a third side of the touch control area that is different from the first side and the second side.

In some implementations, the touch control substrate further includes: a first first connection pad portion, a second first connection pad portion, and a second connection pad portion, where the second connection pad portion is located between the first first connection pad portion and the second first connection pad portion, the first first connection pad portion includes a plurality of first first connection pads, the second first connection pad portion includes a plurality of second first connection pads, the second connection pad portion includes a plurality of second connection pads, and each first first connection pad is electrically coupled to a corresponding first first fan-out line, each second first connection pad is electrically coupled to a corresponding second first fan-out line, and each second connection pad is electrically coupled to a corresponding second fan-out line.

In some implementations, the first first connection pads, the second first connection pads, and the second connection pads are bonded and coupled to a flexible circuit board.

In some implementations, the first signal lead-in terminals are arranged adjacently and at intervals; the second signal lead-in terminals are arranged adjacently and at intervals.

In some implementations, the number of the first signal lead-in terminals is substantially the same as the number of the second signal lead-in terminals.

In some implementations, each first signal line is at least partially arranged between two adjacent rows of touch control units, each second signal line is at least partially arranged between two adjacent columns of touch control units, the plurality of first signal lines and the plurality of second signal lines cross each other and are insulated from each other.

In some implementations, the plurality of first signal lines and the plurality of second signal lines are located in different layers in the base, or the plurality of first signal lines and the plurality of second signal lines are located in different layers in the base only at intersections.

In some implementations, the touch control substrate further includes: a polarizer located on a side of the base close to the plurality of touch control units; a first protective film located on a side of the polarizer away from the plurality of touch control units; and a second protective film located on a side of the base away from the plurality of touch control units.

In some implementations, each touch control unit includes a touch control sensing electrode block, and touch control sensing electrode blocks are arranged at intervals.

In some implementations, the touch control substrate further includes: a plurality of touch control electrode blocks and a plurality of sensing electrode blocks, where sensing electrode blocks located in a same row are coupled to a same first signal line, and every two adjacent sensing electrode blocks are electrically coupled with each other through a connecting portion, touch control electrode blocks located in a same column are coupled to a same second signal line, and every two adjacent touch control electrode blocks are electrically coupled with each other through a bridge portion, the bridge portion and the connection portion are insulated from each other, and each touch control unit comprises one connecting portion and one bridge portion arranged crosswise, two ½ of sensing electrode block and two ½ of touch control electrode block.

In some implementations, a length and a width of the touch control unit range from 4 mm to 4.5 mm, respectively.

In a second aspect, an embodiment of the present disclosure provides a display substrate, which has a display area and includes an array substrate and the touch control substrate as described above, wherein the array substrate includes a plurality of pixel units arranged in a matrix, the plurality of pixel units are located in the display area, and the touch control substrate is located on a light-exiting surface side of the array substrate.

In some implementations, an orthographic projection of the display area on the touch control substrate overlaps the touch control area.

In a third aspect, an embodiment of the present disclosure provides a display device, including a display panel and the touch control substrate as described above, wherein, the touch control substrate is arranged on a light-exiting surface side of the display panel.

In some implementations, the display panel includes an organic light emitting diode panel.

In a fourth aspect, an embodiment of the present disclosure provides a display device including the display substrate as described above.

In a fifth aspect, an embodiment of the present disclosure provides a manufacturing method of a touch control substrate, the touch control substrate having a touch control area and a bonding area, the manufacturing method includes: providing a base; forming a plurality of touch control units arranged in an array, and a plurality of first signal lines and a plurality of second signal lines on the base and in the touch control area, wherein, each of the plurality of first signal lines and the plurality of second signal lines has a signal lead-in terminal, and first signal lead-in terminals of part of the first signal lines are located on a first side of the touch control area, second signal lead-in terminals of the other part of the first signal lines are located on a second side of the touch control area opposite to the first side, and touch control units in a same row are coupled to a same first signal line, and touch control units in a same column are coupled to a same second signal line; forming a plurality of first first fan-out lines, a plurality of second first fan-out lines, and a plurality of second fan-out lines on the base, and electrically coupling the first signal lead-in terminals of the part of the first signal lines to corresponding first first fan-out lines, respectively, electrically coupling the second signal lead-in terminals of the other part of the first signal lines to corresponding second first fan-out lines, respectively, and electrically coupling third signal lead-in terminals of the plurality of second signal lines to corresponding second fan-out lines, respectively, wherein, the first first fan-out lines, the second first fan-out lines, and the second fan-out lines are located in the bonding area, and the bonding area is located at a third side of the touch control area that is different from the first side and the second side.

In some implementations, the manufacturing method further includes: forming a first first connection pad portion, a second first connection pad portion, and a second connection pad portion in the bonding area, wherein the second connection pad portion is located between the first first connection pad portion and the second first connection pad portion, the first first connection pad portion comprises a plurality of first first connection pads, the second first connection pad portion comprises a plurality of second first connection pads, the second connection pad portion comprises a plurality of second connection pads, and each first first connection pad is electrically coupled to a corresponding first first fan-out line, each second first connection pad is electrically coupled to a corresponding second first fan-out line, and each second connection pad is electrically coupled to a corresponding second fan-out line.

In some implementations, the manufacturing method further includes: bonding and coupling the first first connection pads, the second first connection pads, and the second connection pads to a flexible circuit board.

In a sixth aspect, an embodiment according to the present disclosure provides a manufacturing method of a display substrate, which includes: forming an array substrate; forming a touch control substrate using the manufacturing method as described above; and disposing the touch control substrate on a light-exiting surface side of the array substrate.

### BRIEF DESCRIPTION OF THE DRAWINGS

FIG. 1 is a schematic diagram of a structure of a touch control substrate;

FIG. 2 is a schematic diagram of a structure of a touch control substrate according to an embodiment of the present disclosure;

FIG. 3 is a schematic diagram of a structure of a touch control substrate according to the embodiment of the present disclosure; and

FIG. 4 is a schematic diagram of a structure of a touch control substrate according to an embodiment of the present disclosure;

FIG. 5 is a schematic diagram of a touch control unit of a touch control substrate according to an embodiment of the present disclosure;

FIG. 6 is a schematic diagram of a structure of a touch control substrate according to an embodiment of the present disclosure;

FIG. 7 is a flowchart of a method of manufacturing a touch control substrate according to an embodiment of the present disclosure.

### DETAILED DESCRIPTION

In order to enable those skilled in the art to better understand the technical solutions of the present disclosure, the present disclosure will be further described in detail below in conjunction with the accompanying drawings and specific embodiments.

Unless otherwise defined, technical terms or scientific terms used in the present disclosure should be understood as meanings commonly understood by those of ordinary skill in the art to which the present disclosure belongs. “First”, “second” and similar words used in the present disclosure do not indicate any order, quantity or importance, but are only used to distinguish different components. Similarly, similar words such as “a”, “one” or “the” do not indicate quantity limit, but rather indicate that at least one is exist. Similar words such as “include” or “contain” indicate that element or item in front of the word includes elements or items and their equivalents listed after the word, but does not exclude other elements or items. Similar words such as “connect” or “couple” are not limited to physical or mechanical connections, but may include electrical connections, whether direct or indirect. “Above”, “below”, “left”, “right”, etc. are only used to indicate a relative position relationship. When an absolute position of the described object changes, a relative position relationship may also change accordingly.

In the related art, as customers have more and more demands for narrow bezel of the display device, how to realize the narrow bezel of display device is a technical problem that needs to be solved.

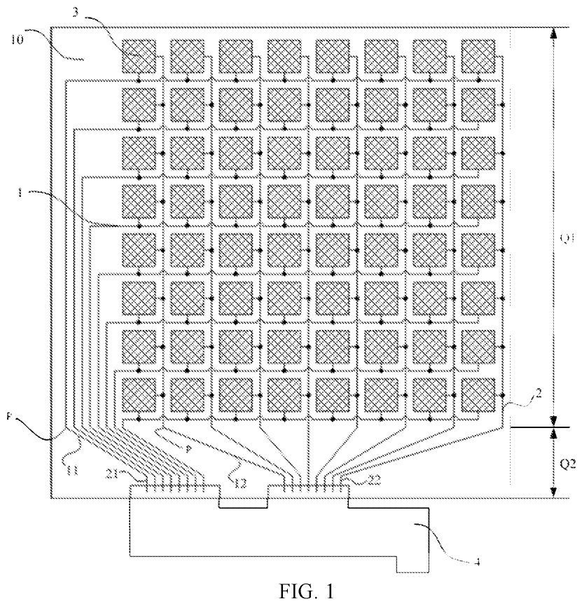

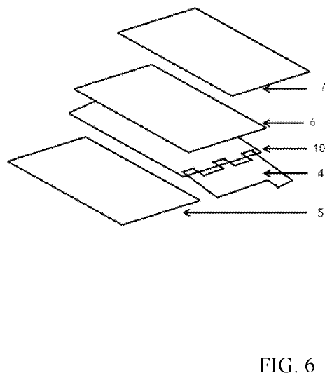

It should be noted here that one of a first signal line and a second signal line in a touch control substrate/display substrate in an embodiment of the present disclosure is a touch control driving line, and the other of the first signal line and the second signal line is a touch control sensing line. In the embodiment of the present disclosure, a case where the first signal line is the touch control sensing line and the second signal line is the touch control driving line is taken as an example for description. A first side and a second side of a touch control area are arranged oppositely. Specifically, the first side refers to the left side in FIGS. 1 to 5, and the second side refers to the right side in FIGS. 1 to 5.

In an example, a structure of a touch control substrate is given. As shown in FIG. 1, the touch control substrate is divided into a touch control area Q1 and a bonding area Q2. The touch control substrate includes: a base 10; a plurality of touch control sensing lines 1 located on the base 10 and arranged in the touch control area Q1, a plurality of touch control driving lines 2; and a plurality of touch control units 3 arranged in an array, where the touch control units 3 in a same row are coupled to a same touch control sensing line 1, and the touch control units 3 in a same column are coupled to a same touch control driving line 2. The touch control substrate further includes: one first connection pad portion and one second connection pad portion located on the base 10 and arranged in the bonding area Q2. The first connection pad portion includes a plurality of first connection pads 21, and the second connection pad portion includes a plurality of second connection pads 22. Each of the plurality of touch control sensing lines 1 and the plurality of touch control driving lines 2 has a signal lead-in terminal P. The signal lead-in terminal P of each touch control sensing line 1 is electrically coupled to a corresponding first connection pad 21 through a first fan-out line 11 corresponding thereto; the signal lead-in terminal P of each touch control driving line 2 is coupled to a corresponding second connection pad 22 through a second fan-out line 12 corresponding thereto. The first connection pads 21 and the second connection pads 22 are bonded and coupled to a flexible circuit board 4. A driving voltage can be applied to the touch control driving lines 2 column by column through a touch control driving chip on the flexible circuit board 4. If touch occurs at a certain position, a touch control signal sensed by a touch unit 3 corresponding to the position is different from the touch control signals sensed by the touch control units 3 corresponding to other positions, the signal related to this position can be output through the touch control sensing line 1 coupled to the touch control unit 3, and a controller on the flexible circuit board 4 can analyze the signal and determine the position where the touch occurs, and a corresponding touch control command can be further executed.

Each touch control sensing line 1 is coupled to a corresponding first fan-out line 11 through the signal lead-in terminal P of its own, and each first fan-out line 11 is coupled to a corresponding first connection pad 21. Since the signal lead-in terminals P of the touch control sensing lines 1 are located on a same side (the left side in FIG. 1), the first fan-out lines 11 are all provided on a same side in the bonding area Q2. In order to prevent the first fan-out lines 11 from being short-circuited, a certain gap is required between adjacent first fan-out lines 11. This will inevitably lead to an increase in a width of the bonding area Q2 in the vertical direction as shown in FIGS. 1 to 3, so that when the flexible circuit board 4 is bent, a width of the bent area will increase. As a result, the narrowing of the bezel of the touch control substrate is limited, and the bending difficulty is increased, the stress on the bent area is also increase, which in turn leads to the connection pads (the first connection pads 21 and the second connection pads 22) located in the bonding area Q2 have a risk of falling off, resulting in poor touch control.

In view of the above problem, the following technical solutions are provided in the embodiments of the present disclosure.

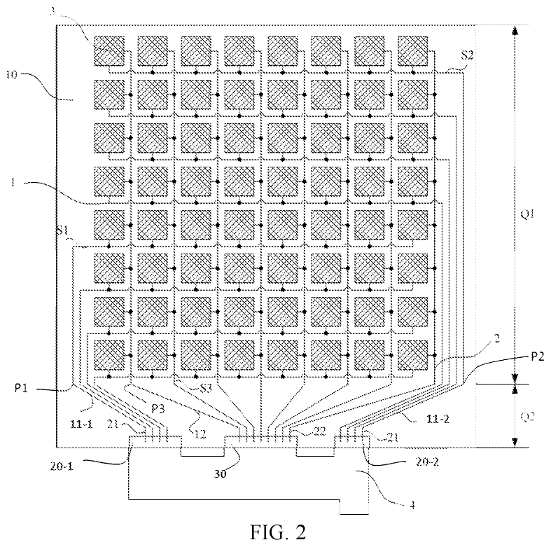

In a first aspect, as shown in FIG. 2, an embodiment of the present disclosure provides a touch control substrate, the touch control substrate is divided into a touch control area Q1 and a bonding area Q2; the touch control substrate includes: a base 10; a plurality of touch control sensing lines 1 and a plurality of touch control driving lines 2 located on the base 10 and arranged in the touch control area Q1; and a plurality of touch control units 3 arranged in an array, where the touch control units 3 in a same row are coupled to a same touch control sensing line 1 and the touch control units 3 located in a same column are coupled to a same touch control driving line 2, where each touch control sensing line 1 is at least partially arranged between two adjacent rows of touch control units, each touch control driving line 2 is at least partially arranged between two adjacent columns of touch control units, and the plurality of touch control sensing lines 1 and the plurality of touch control driving lines 2 cross each other and are insulated from each other. The plurality of touch control sensing lines 1 and the plurality of touch control driving lines 2 are located in different layers in the base, or the plurality of touch control sensing lines 1 and the plurality of touch control driving lines 2 are located in different layers in the base only at the intersections thereof. The touch control substrate further includes: two first connection pad portions located on the base 10 and arranged in the bonding area Q2, namely, a first first connection pad portion 20-1 and a second first connection pad portion 20-2, and one second connection pad portion 30, wherein the second connection pad portion 30 is located between the first first connection pad portion 20-1 and a second first connection pad portion 20-2two first connection pad portions. Among them, each of the plurality of touch control sensing lines 1 and the plurality of touch control driving lines 2 has a signal lead-in terminal (as shown in FIG. 2, P1, P2, and P3). The first signal lead-in terminals P1 of part of the touch control sensing lines 1 (part S1) are on the first side (left side) of the touch control substrate (or the touch control area Q1), and the second signal lead-in terminals P2 of the other part of the touch control sensing lines 1 (part S2) are on the second side (right side) of the touch control substrate (or the touch control area Q1). These two first connection pad portions respectively include a plurality of first connection pads 21 (that is, the first first connection pad portion 20-1 includes a plurality of first first connection pads 21, and the second first connection pad portion 20-1 includes a plurality of second first connection pads 21), the second connection pad portion 30 includes a plurality of second connection pads 22, and the signal lead-in terminals P1 and P2 of the touch control sensing lines 1 are respectively coupled to the corresponding first connection pads 21 through the first fan-out lines 11 corresponding thereto, and each the first connection pads 21 is are coupled to one the first fan-out lines 11 one to one. The third signal lead-in terminals P3 of the touch control driving lines 2 (also shown as S3 in FIG. 2) are coupled to the corresponding second connection pads 22 through the corresponding second fan-out lines 12, and each the second connection pads 22 is are coupled to one the second fan-out lines 12 one to one. The first connection pads 21 and the second connection pads 22 are bonded and coupled to a flexible circuit board 4. A driving voltage is applied to the touch control driving lines 2 column by column through a touch control driving chip on the flexible circuit board 4. If a touch occurs at a certain position, a touch control signal sensed by a touch control unit 3 corresponding to the position is different from the touch control signals sensed by the touch control units 3 corresponding to other positions, the signal related to this position can be output through the touch control sensing line 1 coupled to the touch control unit 3, and a controller on the flexible circuit board 4 can analyze the signal and determine the position where the touch occurs, and a corresponding touch control command can be further executed.

In the touch control substrate according to the embodiment of the present disclosure, as shown in FIG. 2, the second connection pads 22 are located in the middle part of the bonding area Q2 of the touch control substrate. Since the first signal lead-in terminals P1 of part of the touch control sensing lines 1 are located on the first side (left side) of the touch control substrate, and the second signal lead-in terminals P2 of the other part of the touch sensing lines 1 are located on the second side of the touch control substrate opposite to the first side, when the first signal lead-in terminal P1 of the touch control sensing lines 1 are coupled to the first connection pads 21 through the corresponding first fan-out lines 11, part of the first fan-out lines 11 (first first fan-out lines 11-1) and the first first connection pad portion 20-1 coupled thereto are located on the first side (left side) of the second connection pad portion 30; the remaining part of the first fan-out lines 11 (second first fan-out lines 11-2) and the second first connection pad portion 20-2 coupled thereto are located on the second side (right side) of the second connection pad portion 30.

The first connection pads 21 and the second connection pads 22 are divided into three parts which are respectively arranged in the bonding area Q2 of the touch control substrate. In this way, the stress when the flexible circuit board 4 is bent can be effectively dispersed, and the width of the bent area will not increase, so that a narrow bezel of the touch control substrate can be realized, and a risk of falling off of the connection pads (the first connection pads 21 and the second connection pads 22) located in the bonding area Q2 can also be avoided.

In some implementations, the first signal lead-in terminals P1 of half of the touch control sensing lines 1 are located on the first side of the touch control substrate, and the second signal lead-in terminals P2 of the other half of the touch control sensing lines 1 are located on the second side of the touch control substrate. That is, half of the first fan-out lines 11 are located on the left side of the second fan-out lines 12, and the other half of the first fan-out lines 11 are located on the right side of the second fan-out lines 12. In this way, the stress on the bonding area Q2 when it is bent is evenly distributed, and the risk of falling off of the connection pads (the first connection pads 21 and the second connection pads 22) of the bonding area Q2 can be reduced as much as possible.

In some implementations, the first fan-out lines 11 on the first side of the touch control substrate are arranged adjacently; the first fan-out lines on the second side of the touch control substrate are arranged adjacently. Through this connection method, the width of the bonding area Q2 in the vertical direction as shown in FIGS. 1 to 3 is reduced, and the bonding between the first connection pads 21 and the flexible circuit board 4 is facilitated. According to some implementations, the signal lead-in terminals of the touch control sensing lines 1 in odd-numbered rows are located on the first side of the touch control substrate, and the signal lead-in terminals of the touch control sensing lines 1 in even-numbered rows are located on the second side of the touch control substrate; alternatively, the signal lead-in terminals of the touch control sensing lines 1 in odd-numbered rows are located on the second side of the touch control substrate, and the signal lead-in terminals of the touch control sensing lines 1 in even rows are located on the first side of the touch control substrate. As long as not all the signal lead-in terminals of the touch control sensing lines 1 are located on the same side of the touch substrate.

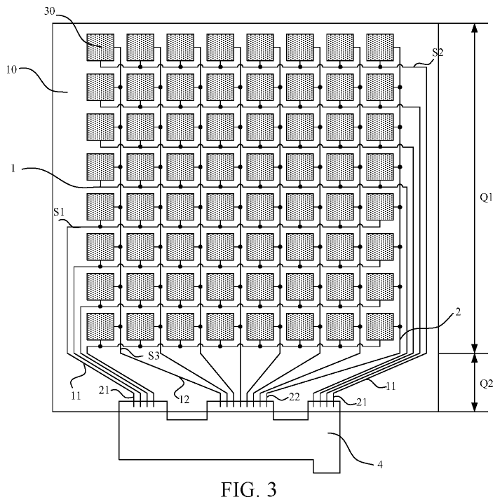

In some implementations, as shown in FIG. 3, the touch control substrate may be a self-capacitive touch control substrate, and each touch control unit 3 includes a touch control sensing electrode block 30, and touch control sensing electrode blocks 30 are arranged at intervals. The touch control sensing electrode blocks 30 located in a same row are coupled to a same touch control sensing line 1, and the touch control sensing electrode blocks 30 located in a same column are coupled to a same touch control driving line 2. The driving voltage is applied column by column to the touch control sensing electrode blocks 30 through the touch control driving chip on the flexible circuit board 4. If a touch occurs at a certain position, a touch control signal sensed by a touch control sensing electrode block 30 corresponding to the position is different from the touch control signals sensed by the touch control sensing electrode blocks 30 corresponding to other positions, the signal related to this position can be output through the touch control sensing line 1 coupled to the touch control sensing electrode block 30, and a controller on the flexible circuit board 4 can analyze the signal and determine the position where the touch occurs, and a corresponding touch control command can be further executed.

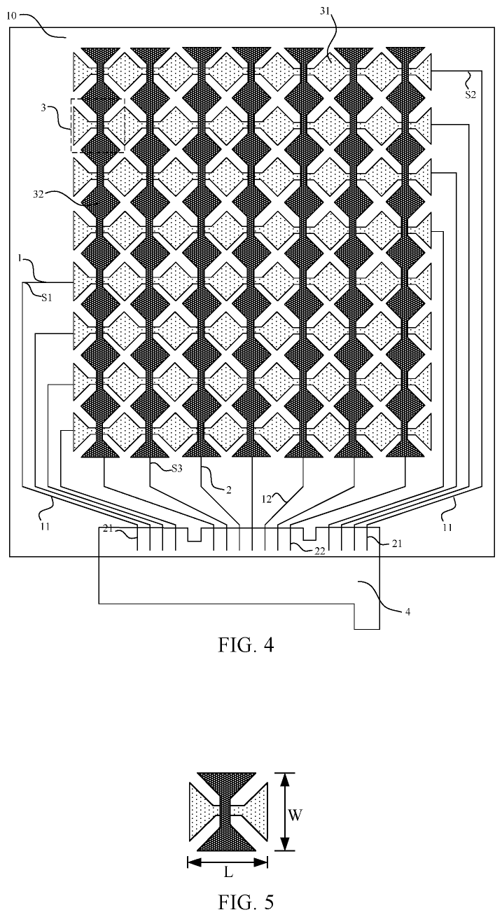

In some implementations, as shown in FIG. 4, the touch control substrate may be a mutual-capacitive touch control substrate. The touch control substrate includes a plurality of touch control electrode blocks 32 and a plurality of sensing electrode blocks 31. The sensing electrode blocks 31 located in a same row are coupled to a same touch control sensing line 1, and every two adjacent sensing electrode blocks 31 are coupled through a connecting portion; the touch control electrode blocks 32 located in a same column are coupled to a same touch control driving line 2, and every two adjacent touch control electrode blocks 32 are coupled through a bridge portion; the bridge portion and the connection portion are insulated from each other. As shown in FIG. 4, each touch control unit 3 includes a connecting portion and a bridging portion arranged crosswise, two ½ (half) of the sensing electrode block 31 and two ½ (half) of the touch control electrode block 32.

In some implementations, as shown in FIG. 4, ranges of the length L and the width W of the touch control unit 3 may be, but not limited to, 4 mm-4.5 mm. A size of the touch control unit 3 needs to be specifically set according to the specific panel to which it is applied.

In some implementations, as shown in FIG. 6, the touch control substrate not only includes the above structures, but also includes: a polarizer 6 located on a side of the base close to the touch control unit 3; and a first protective film 7 located on a side of the polarizer 6 away from the touch control unit 3; and a second protective film 5 located on a side of the base away from the touch control unit 3.

In a second aspect, according to an embodiment of the present disclosure, a display device is provided, which includes the above-mentioned touch control substrate and a display panel, where the touch control substrate is located on a light-exiting surface side of the display panel. Specifically, the touch control substrate can be adhered to the display panel through a transparent optical adhesive (OCA), that is, the display device is an on-cell display device.

Since the display device according to the embodiment of the present disclosure includes the above-mentioned touch control substrate, its bezel is narrower and the yield rate is higher.

In some implementations, the display panel is an organic light emitting diode (OLED) display panel. Certainly, the display panel can also be electronic paper, a liquid crystal display panel, or the like.

In a third aspect, according to an embodiment of the present disclosure, a display substrate having a display area is provided; the display substrate includes an array substrate and the touch control substrate as described above, wherein the array substrate includes a plurality of pixel units arranged in a matrix, the plurality of pixel units are located in a the display area, and the touch control substrate is located on at a light emitting surface side of the array substrate. Wherein, An the orthographic projection of the display area on the touch control substrate completely falls within the a range of a touch control area of the touch control substrate.

It should be noted here that in the embodiment according to the present disclosure, the structures of the touch control units 3, the arrangement and positions of the touch control sensing lines 1 and the touch control driving lines 2; and the structures of the first connection pads 21 and the second connection pads 22 are the same as those in the above-mentioned touch control substrate, so the description will not be repeated here. In a fourth aspect, according to an embodiment of the present disclosure, a display device is provided, which includes the above-mentioned display substrate.

Since the display device according to the embodiment of the present disclosure includes the above-mentioned display substrate, its bezel is narrower and the yield rate is higher.

The display device in this embodiment may be any product or component with display function such as electronic paper, an OLED panel, a mobile phone, a tablet computer, a television, a monitor, a notebook computer, a digital photo frame, a navigator, etc.

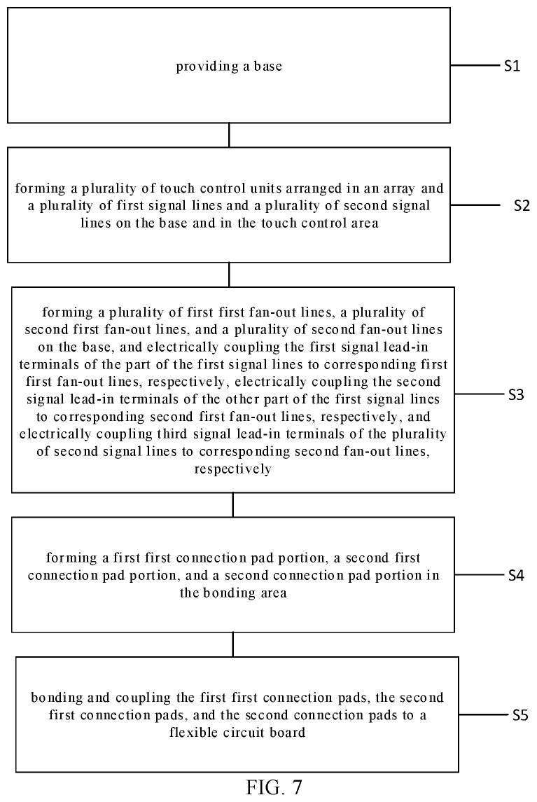

In a fifth aspect, according to an embodiment of the present disclosure, a manufacturing method of a touch control substrate is provided, the touch control substrate having a touch control area and a bonding area, as shown in FIG. 7, the manufacturing method includes: providing a base (step S1); forming a plurality of touch control units arranged in an array on the base and in the touch control area and a plurality of first signal lines and a plurality of second signal lines (step S2), where, each of the plurality of first signal lines and the plurality of second signal lines has a signal lead-in terminal, and first signal lead-in terminals of part of the first signal lines are located on a first side of the touch control area, second signal lead-in terminals of the other part of the first signal lines are located on a second side of the touch control area opposite to the first side, and touch control units located in a same row are coupled to a same first signal line and touch control units located in a same column are coupled to a same second signal line; forming a plurality of first first fan-out lines, a plurality of second first fan-out lines, and a plurality of second fan-out lines on the base, electrically coupling first signal lead-in terminals of the part of the first signal lines to the corresponding first first fan-out lines, respectively, electrically coupling second signal lead-in terminals of the other part of the first signal lines to the corresponding second first fan-out lines, respectively, and electrically coupling third signal lead-in terminals of the plurality of second signal lines to the corresponding second fan-out lines, respectively (step S3), where, the first first fan-out lines, the second first fan-out lines, and the second fan-out lines are located in the bonding area, and the bonding area is located in a third side of the touch control area other than the first side and the second side.

The manufacturing method further includes: forming a first first connection pad portion, a second first connection pad portion, and a second connection pad portion in the bonding area (step S4), where the second connection pad portion is located between the first first connection pad portion and the second first connection pad portion, and the first first connection pad portion includes a plurality of first first connection pads, the second first connection pad portion includes a plurality of second first connection pads, the second connection pad portion includes a plurality of second connection pads, and each first first connection pad is electrically coupled to a corresponding first first fan-out line, each second first connection pad is electrically coupled to a corresponding second first fan-out line, and each second connection pad is electrically coupled to a corresponding second fan-out line.

The manufacturing method further includes: binding and coupling each first first connection pad, each second first connection pad, and each second connection pad to a flexible circuit board (step S5).

The steps of the manufacturing method of the touch control substrate according to the embodiment of the present disclosure are not limited to the above-mentioned order.

In a sixth aspect, according to an embodiment of the present disclosure, a manufacturing method of a display substrate is provided, the display substrate having a display area, the manufacturing method includes: forming an array substrate; forming a touch control substrate using the manufacturing method as described above; and disposing the touch control substrate on the light-exiting surface side of the array substrate.

In a seventh aspect, according to an embodiment of the present disclosure, a manufacturing method of a display device is provided, the manufacturing method includes: forming a display panel; forming a touch control substrate using the manufacturing method as described above; and disposing the touch control substrate on light-exiting surface side of the display panel.

It can be understood that the above embodiments are merely exemplary embodiments used to illustrate the principle of the present disclosure, but the present disclosure is not limited thereto. For those of ordinary skill in the art, various modifications and improvements can be made without departing from the spirit and essence of the present disclosure, and these modifications and improvements are also deemed to be within the protection scope of the present disclosure.

1. A touch control substrate, having a touch control area and a bonding area, and comprising:
a base;
a plurality of first signal lines and a plurality of second signal lines on the base;
a plurality of touch control units arranged in an array on the base and in the touch control area, and
wherein, touch control units in a same row are coupled to a same first signal line and touch control units in a same column are coupled to a same second signal line,
wherein each of the plurality of first signal lines and the plurality of second signal lines has a signal lead-in terminal, and first signal lead-in terminals of part of the first signal lines are located on a first side of the touch control area, second signal lead-in terminals of the other part of the first signal lines are located on a second side of the touch control area opposite to the first side,
wherein the first signal lead-in terminals of the part of the first signal lines are electrically coupled to corresponding first first fan-out lines, respectively, the second signal lead-in terminals of the other part of the first signal lines are electrically coupled to second first fan-out lines, respectively, and the first first fan-out lines and the second first fan-out lines are located in the bonding area,
wherein third signal lead-in terminals of the plurality of second signal lines are electrically coupled to corresponding second fan-out lines, respectively, the second fan-out lines are located in the bonding area, and
the bonding area is located at a third side of the touch control area that is different from the first side and the second side.

2. The touch control substrate of claim 1, further comprising: a first first connection pad portion, a second first connection pad portion, and a second connection pad portion, wherein the second connection pad portion is located between the first first connection pad portion and the second first connection pad portion, the first first connection pad portion comprises a plurality of first first connection pads, the second first connection pad portion comprises a plurality of second first connection pads, the second connection pad portion comprises a plurality of second connection pads, and each first first connection pad is electrically coupled to a corresponding first first fan-out line, each second first connection pad is electrically coupled to a corresponding second first fan-out line, and each second connection pad is electrically coupled to a corresponding second fan-out line.

3. The touch control substrate of claim 2, wherein, the first first connection pads, the second first connection pads, and the second connection pads are bonded and coupled to a flexible circuit board.

4. The touch control substrate of claim 1, wherein, the first signal lead-in terminals are arranged adjacently and at intervals; the second signal lead-in terminals are arranged adjacently and at intervals.

5. The touch control substrate of claim 1, wherein, the number of the first signal lead-in terminals is substantially the same as the number of the second signal lead-in terminals.

6. The touch control substrate of claim 1, each first signal line is at least partially arranged between two adjacent rows of touch control units, each second signal line is at least partially arranged between two adjacent columns of touch control units, the plurality of first signal lines and the plurality of second signal lines cross each other and are insulated from each other.

7. The touch control substrate of claim 6, the plurality of first signal lines and the plurality of second signal lines are located in different layers in the base, or the plurality of first signal lines and the plurality of second signal lines are located in different layers in the base only at their intersections.

8. The touch control substrate of claim 1, further comprising:
a polarizer located on a side of the base close to the plurality of touch control units;
a first protective film located on a side of the polarizer away from the plurality of touch control units; and
a second protective film located on a side of the base away from the plurality of touch control units.

9. The touch control substrate of claim 1, each touch control unit comprises a touch control sensing electrode block, and touch control sensing electrode blocks are arranged at intervals.

10. The touch control substrate of claim 1, further comprising: a plurality of touch control electrode blocks and a plurality of sensing electrode blocks,
wherein, sensing electrode blocks located in a same row are coupled to a same first signal line, and every two adjacent sensing electrode blocks are electrically coupled with each other through a connecting portion,
touch control electrode blocks located in a same column are coupled to a same second signal line, and every two adjacent touch control electrode blocks are electrically coupled with each other through a bridge portion,
the bridge portion and the connection portion are insulated from each other, and
each touch control unit comprises one connecting portion and one bridge portion arranged crosswise, two ½ of sensing electrode block and two ½ of touch control electrode block.

11. The touch control substrate of claim 1, wherein, a length and a width of the touch control unit range from 4 mm to 4.5 mm, respectively.

12. A display substrate, which has a display area and comprises an array substrate and the touch control substrate of claim 1, wherein the array substrate comprises a plurality of pixel units arranged in a matrix, the plurality of pixel units are located in the display area, and the touch control substrate is located on a light-exiting surface side of the array substrate.

13. The display substrate of claim 12, wherein, an orthographic projection of the display area on the touch control substrate overlaps the touch control area.

14. A display device, comprising a display panel and the touch control substrate of claim 1, wherein, the touch control substrate is arranged on a light-exiting surface side of the display panel.

15. The display device of claim 14, wherein, the display panel comprises an organic light emitting diode panel.

16. A display device, comprising the display substrate of claim 12.

17. A manufacturing method of a touch control substrate, the touch control substrate having a touch control area and a bonding area, the manufacturing method comprising:
providing a base;
forming a plurality of touch control units arranged in an array and a plurality of first signal lines and a plurality of second signal lines on the base and in the touch control area, wherein, each of the plurality of first signal lines and the plurality of second signal lines has a signal lead-in terminal, and first signal lead-in terminals of part of the first signal lines are located on a first side of the touch control area, second signal lead-in terminals of the other part of the first signal lines are located on a second side of the touch control area opposite to the first side, and touch control units in a same row are coupled to a same first signal line, and touch control units in a same column are coupled to a same second signal line;
forming a plurality of first first fan-out lines, a plurality of second first fan-out lines, and a plurality of second fan-out lines on the base, and electrically coupling the first signal lead-in terminals of the part of the first signal lines to corresponding first first fan-out lines, respectively, electrically coupling the second signal lead-in terminals of the other part of the first signal lines to corresponding second first fan-out lines, respectively, and electrically coupling third signal lead-in terminals of the plurality of second signal lines to corresponding second fan-out lines, respectively, wherein, the first first fan-out lines, the second first fan-out lines, and the second fan-out lines are located in the bonding area, and the bonding area is located at a third side of the touch control area that is different from the first side and the second side.

18. The manufacturing method of claim 17, further comprising:
forming a first first connection pad portion, a second first connection pad portion, and a second connection pad portion in the bonding area, wherein the second connection pad portion is located between the first first connection pad portion and the second first connection pad portion, the first first connection pad portion comprises a plurality of first first connection pads, the second first connection pad portion comprises a plurality of second first connection pads, the second connection pad portion comprises a plurality of second connection pads, and each first first connection pad is electrically coupled to a corresponding first first fan-out line, each second first connection pad is electrically coupled to a corresponding second first fan-out line, and each second connection pad is electrically coupled to a corresponding second fan-out line.

19. The manufacturing method of claim 17, further comprising: bonding and coupling the first first connection pads, the second first connection pads, and the second connection pads to a flexible circuit board.

20. A manufacturing method of a display substrate, comprising:
forming an array substrate;
forming a touch control substrate using the manufacturing method of claim 17; and
disposing the touch control substrate on a light exiting surface side of the array substrate.
